(19) United States
(12) Patent Application Publication
(10) Pub. No.: US 2004/0053447 A1
(43) Pub. Date: Mar. 18, 2004

(54) Leadframe having fine pitch bond fingers formed using laser cutting method

(76) Inventors: Donald Craig Foster, Mesa, AZ (US); Kelly Robbins McKendrick SR., Higley, AZ (US)

Correspondence Address: Bever Hoffman & Harms, 2099 Gateway Place, Suite 320, San Jose, CA, 95110-1017, US

(21) Appl. No.: 09/895,501

(22) Filed: Jun. 29, 2001

(51) Int. Cl. H01L 21/60

(52) U.S. Cl. 438/123

(57) ABSTRACT

Methods of making a leadframe and a semiconductor package made using the leadframe are disclosed. One embodiment of such a method includes providing a metal sheet and patterning the metal sheet to form a plurality of leads. An inner end portion of each lead is joined into a block with the inner end portion of one or more adjacent leads. Subsequently, the end block is cut with a laser to singulate the inner end portion of each of the leads from the end block. This method can further comprise reducing a thickness of the end block relative to an initial thickness of the metal sheet, prior to the laser cutting step, to make the laser cutting easier.

### BACKGROUND

1. Field of the Invention

The present invention relates to packages for semiconductor chips or other electronic devices.

2. Background Information

A typical package for a semiconductor chip includes an internal metal leadframe, which functions as a substrate for the package. The leadframe includes a central die pad and a plurality of leads that radiate outward from the die pad. A hardened, insulative encapsulant material covers the die, die pad, and an inner portion of each of the leads.

The semiconductor chip is mounted on the die pad and is electrically connected to the leads. In particular, the chip includes a plurality of bond pads, each of which is electrically connected by a bond wire or the like to a bond finger that is at an inner end of one of the leads. An outer portion of each lead extends outward from the encapsulant, and serves as an input/output terminal for the package. The outer portion of the leads may be bent into various configurations, such as a J lead configuration or a gull wing configuration.

In the market for semiconductor packaging today, there is a trend toward decreasing the bond finger pitch and/or the size of the die pad. This is driven by semiconductor die size reductions that accompany each new generation of fabrication processes. As the die size shrinks, so must the bond finger pitch, otherwise wire lengths get too long and mold yield suffers due to wire sweep. Reducing bond finger pitch allows the bond fingers to extend further into the package, which allows for shorter wire lengths. This in turn increases quality and yields, enhances electrical performance, and increase productivity.

In keeping with these trends, ever finer leads and bond finger pitches are required. It can be difficult to meet this industry need while also keeping the cost of the package within reason. Limitations on known methods for making leads and bond fingers, such as chemical etching or mechanical stamping, also makes meeting industry needs difficult, as these methods have inherent limitations as to how fine and dense the leads and the bond fingers can be made. At the same time, the bond fingers must be wide enough to serve as a site for electrical connection to a wire or some other conductor that electrically connects the respective bond finger to the chip. Accordingly, an improved method of making a leadframe is desirable.

### SUMMARY

The present invention provides leadframes having a minimal space between the bond fingers of adj acent leads, thereby reducing the bond finger pitch. Correspondingly smaller die pads can be made with such bond fingers than is achievable by conventional methods.

In accordance with one embodiment of the invention, a method of making a leadframe comprises providing a metal sheet; patterning the metal sheet to form a plurality of leads that are integrally joined in an end block at an inner end of the leads; and cutting the end block with a laser to singulate the inner end portion of each lead from the end block. The patterning of the metal sheet to form the leads and end block can be carried out using a masking and etching process, or a stamping process. This method can further comprise reducing a thickness of the end block relative to an initial thickness of the metal sheet prior to laser-forming the inner end portion of the leads, which can facilitate the lasering step.

These and other aspects of the present invention will be more apparent in view of the following detailed description of the exemplary embodiments and the accompanying drawings thereof.

### BRIEF DESCRIPTION OF THE DRAWINGS

FIG. 1 is a top plan view of a leadframe.

FIG. 2 is a plan view of a portion of a leadframe at an intermediate stage of manufacture, wherein an inner end portion of a plurality of leads are integrally joined in an end block.

FIG. 3 is a plan view of the leadframe of FIG. 2, wherein the end block has been laser cut to singulate the bond fingers of the leads.

FIG. 4 is a cross-sectional side view of a semiconductor package.

FIG. 5 is a plan view of a portion of a leadframe wherein two leads are tied together.

FIG. 6 is a plan view of a portion of a leadframe with an alternative bond finger shape.

In the drawings, like features are typically labeled with the same reference numbers across the various drawings.

### DETAILED DESCRIPTION

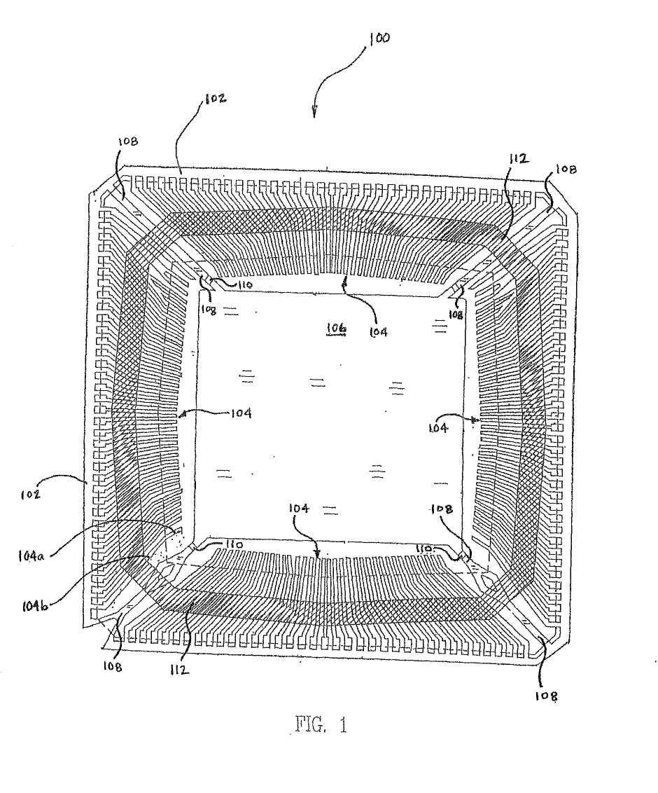

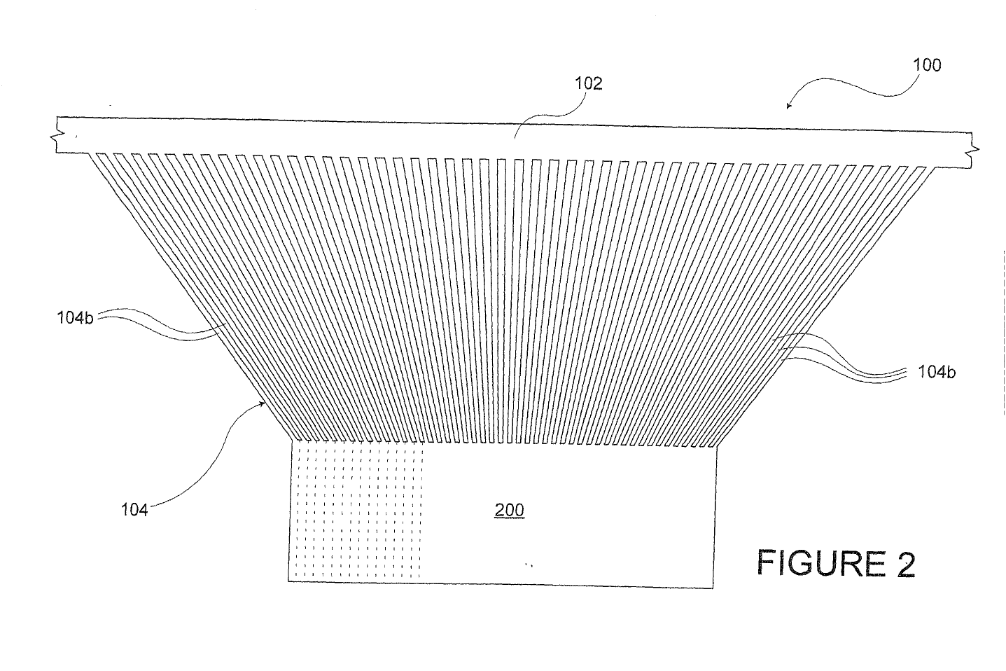

FIG. 1 is a top plan view of a portion of a leadframe 100 that will provide context for the discussion below. Practitioners will appreciate that the techniques of the present invention may be used to make leadframes having a wide variety of configurations. Accordingly, the overall configuration of leadframe 100 is exemplary only.

Leadframe 100 is formed from a metal, such as copper. Other metals also can be used, including, but not limited to, copper alloys, plated copper, plated copper alloys, copper plated steel, Alloy 42, Alloy 37, or any other material that is conductive and can be used for making leadframes. Typically, a plurality of leadframes are formed in a contiguous metal sheet, and the leadframes of the sheet are processed through package assembly in strip form.

Leadframe 100 includes a closed internal frame, denoted as dam bar 102, that supports a plurality of leads 104 and a planar rectangular die pad 106. Although not shown in FIG. 1, leads 104 may extend outward beyond dam bar 102. In such a case, the portion of leads 104 inside of dam bar 102 would be called “inner leads,” and the portion of leads 104 outside of dam bar 102 would be called “outer leads.” The portion of leads 104 within dam bar 102 is encapsulated later in the assembly process.

Die pad 106 is at a central region of leadframe 100 and serves as a base upon which a semiconductor chip is ultimately mounted. Each of the four corners of die pad 106 is connected by a tie bar 108 to dam bar 102. A downset 110 is provided in tie bars 108 so that die pad 106 is vertically below leads 104. Dam bar 102 will be severed from leads 104 and tie bars 108 after an encapsulation step during package assembly, thereby leaving the package with a plurality of encapsulated leads 104 that are electrically isolated from each other.

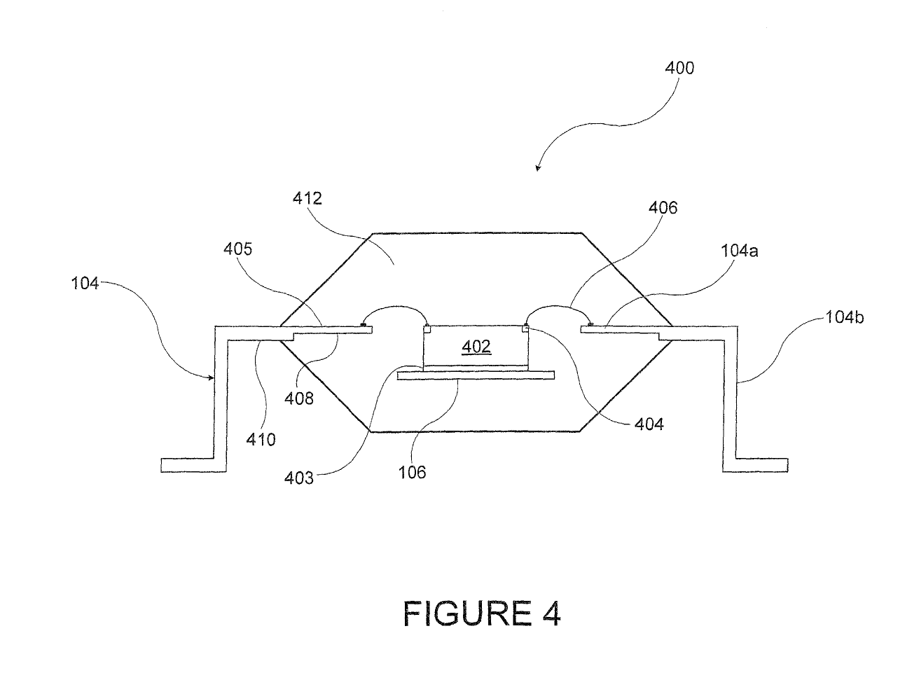

Leads 104 extend inward from dam bar 102 toward all four sides of die pad 106, as in a quad package. Each lead 104 has an inner end segment, denoted herein as bond finger 104a, that is proximate to die pad 106, and a longer, outer second portion 104b that is between bond finger 104a and dam bar 102. In FIG. 1, bond fingers 104a are shown within the dashed line. Ultimately, the bond finger 104a of each of the leads 104 is electrically connected by a bond wire, tab, or some other electrical conductor to the semiconductor chip that is to be mounted on die pad 106 (see, e.g., FIG. 4). Typically, bond fingers 104a of leads 104 are plated with silver or some other common metal to facilitate connection to the bond wire or other conductor that extends to the chip. A nonconductive adhesive strip 112, which may be formed of polyimide, may be applied in a ring onto second portion 104b of leads 104 for stability during processing and to maintain leads 104 at proper positions relative to one another. This can help to prevent two adjacent leads 104 from bending.

As mentioned, leadframe 100 is normally formed from a solid rectangular metal sheet that is patterned to create the configuration shown in FIG. 1. Conventionally, the patterning process involves either a chemical etching process or a mechanical stamping process.

A typical chemical etching process uses photolithography, a photoresist mask, and a metal-dissolving liquid chemical to etch a pattern into the metal sheet that is being used to make leadframe 100. The liquid chemical etches away all portions of the metal sheet not masked by the photoresist mask, leaving behind the desired pattern that forms leadframe 100. The stamping process, on the other hand, uses a series of progressive dies to cut out portions of the metal sheet to create leadframe 100.

As mentioned above, there is a trend in the industry toward reducing bond finger pitch. There are, however, several constraints that limit how much bond finger pitch can be reduced when they are made using the conventional methods described above. Some of these constraints generally stem from the fabrication techniques used to form leads. For instance, the width of the spaces between bond fingers 104a can only be minimized so far using conventional etching and stamping techniques. Another constraint is the width of each bond finger 104a. There is a limit to how much the width of bond fingers 104a can be minimized because the surface area of bond fingers 104a cannot go below a standard limit for the attachment of bond wires or other chip coupling means. Bond fingers 104a must allow for the space taken up by the bond wire or other chip coupling means, as well as allowing for tolerances in the bonding system. Although the width of bond fingers 104a can decrease as wire diameters decrease, it is still desirable to decrease the spaces between bond fingers 104a as well.

The present invention provides for reducing the spacing between adjacent bond fingers 104a, and thereby achieves tighter packing of leads 104 and extends leads 104 further into the package, while maintaining the width of the bond fingers 104a at a width appropriate for whatever types of conductor (e.g., bond wires) and conductor attaching equipment that are used to electrically connect the bond fingers 104a to the semiconductor chip to be mounted on the leadframe. To achieve this objective, the conventional methods of forming bond fingers 104a (i.e., wet chemical etching and/or mechanical stamping) must be discarded, since these methods are relatively crude and leave considerable unused space between bond fingers 104a.

In accordance with embodiments of the present invention, bond fingers 104a are formed using a fine laser beam. The use of such a laser beam to form bond fingers 104a allows for a substantial decrease in the width of the spaces between the bond fingers, which in turn allows for tighter packing of leads 104. A method of making a leadframe in accordance with one embodiment of the present invention uses two steps for forming the leadframe. A first step employs chemical etching, mechanical stamping, or some other metal removal method to pattern a metal sheet to create the above-described portions of leadframe 100, except for the bond finger 104a of the inner end portion of the leads 104. A second step uses a fine laser beam to form the bond fingers 104a of the leads 104.

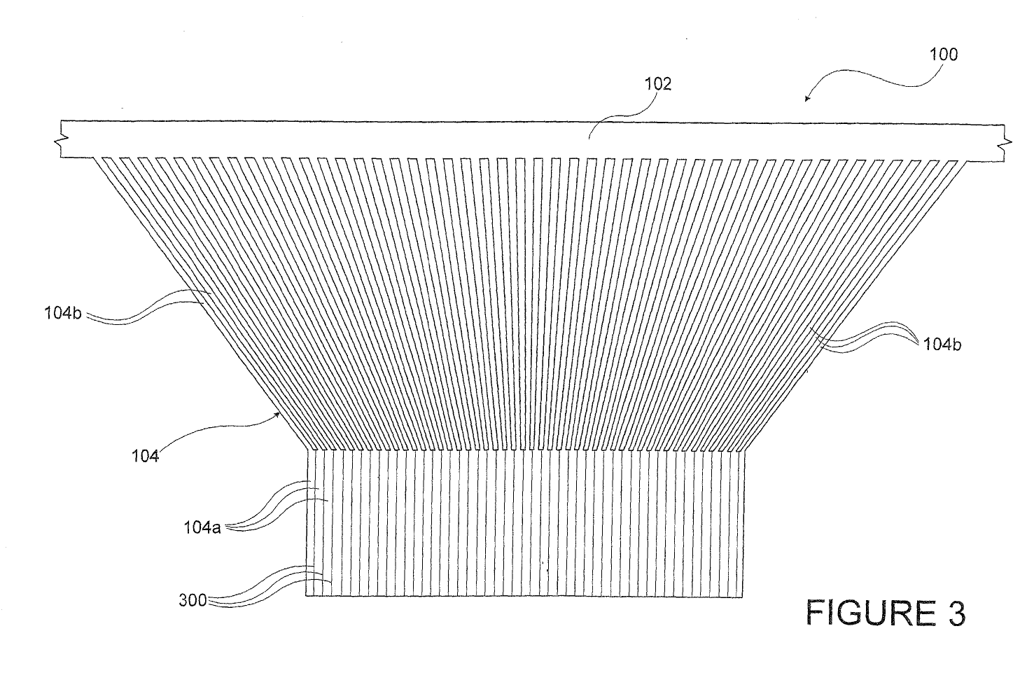

FIG. 2 is a plan view of a portion of an incomplete leadframe 100 after the first step of the above-described two-step process. In particular, the portion of leadframe 100 shown here consists of leads 104 and dam bar 102. The inner end portions of the leads 104 are not separate, but rather are integrally joined in a block, called end block 200 herein. This may be done, for example, by modifying the photoresist mask used in an etching process, or by modifying the dies in a stamping operation, that initially patterns the metal sheet. Second portions 104b of leads 104 are joined to dam bar 102 at one end and to end block 200 at the other. Dashed lines 202 in FIG. 2 represent the boundaries of the individual bond fingers that will be formed after the second step of the above-mentioned two-step process.

FIG. 3 is a plan view of the same portion of leadframe 100 as shown in FIG. 2 after end block 200 has been separated into individual bond fingers 104a in accordance with the above-mentioned two-step process. Here, rather than using etching or stamping techniques, the formation of bond fingers 104a is carried out using a laser, and in particular, a narrow beam laser. For example, a diode pumped YAG laser from the Rofin Basil/Sinar company of Germany may be used. The laser beam is directed at end block 200 and cuts through end block 200 to form individual bond fingers 104a, as shown in FIG. 3. The laser beam forms ultra-narrow spaces 300 between adjacent bond fingers 104a. Each space 300 is sufficient to electrically isolate the bond fingers 104a that are on either side of the space 300 from one another. Unlike in previous chemical etching or stamping techniques, however, this spacing between adjacent bond fingers is substantially minimized, thereby allowing leads 104 and bond fingers 104a to be packed more tightly within leadframe 100. This tighter packing of leads 104 and bond fingers 104a also provides room for additional leads 104 and bond fingers 104a if so desired. The width of bond fingers 104a shown in FIG. 3 corresponds to at least the minimum width necessary for the attachment of bond wires or other chip coupling means.

In another embodiment of a method of forming a leadframe in accordance with the present invention, one can half-etch away or otherwise remove a portion of the thickness of end block 200 prior to the laser-cutting step. The portion may include a top, bottom, and/or side surface of end block 200. The amount removed may be, for example, 50% or 33% to 75% of the thickness of end block 200. This process of half-etching end block 200 is generally done as part of an initial step that forms leadframe 100 of FIG. 2, but can alternatively be done in a second etching step or removal step that takes place after the incomplete leadframe of FIG. 2 is formed. In the half-etch step, the etchant proceeds to etch through the exposed portion of end block 200, and when the etchant has etched a selected distance through the thickness of end block 200, the etching process is halted. The reduction in thickness of end block 200 can make the subsequent laser cutting easier and cleaner, and can increase the cutting speed of the laser.

FIG. 4 is a cross-sectional side view of a semiconductor package 400 made using the laser method described above with respect to FIGS. 2 and 3. Semiconductor package 400 includes a semiconductor chip 402 mounted on die pad 106 using an adhesive layer 403, which may be any conventional adhesive, adhesive film, or adhesive tape, among other possibilities. Die pad 106 is downset from leads 104. Chip 402 has a plurality of bond pads 404 that are each electrically coupled to an upper side 405 of a respective one of the bond fingers 104a of leads 104 by a metal (e.g. gold) bond wire 406. In other embodiments, this electrical coupling can be facilitated by means other than bond wires 406, such as tabs.

In semiconductor package 400 of FIG. 4, bond fingers 104a are formed by a laser cutting process as described above. Therefore, each bond finger 104a of lead 104 is separated from its neighboring bond fingers 104a by a pair of narrow spaces 300 (see FIG. 3) created using a laser beam. Bond fingers 104a are also shown as having a lesser thickness (approximately half the thickness) as the remaining second portion 104b of lead 104, in accordance with the above-described optional step of reducing the thickness of bond fingers 104a prior to laser cutting. In particular, a recessed horizontal surface 408 is formed in lower side 410 of the leads 104 at bond finger 104a.

Semiconductor package 400 also includes an encapsulant 412 that covers die pad 106, chip 402, bond wires 406, bond fingers 104a, and second portion 104b of leads 104. Encapsulant 412 is typically a nonconductive polymer that is molded and cured to harden. The outer, unencapsulated portions of leads 104 may be bent into a variety of configurations, such as gull wing or J-lead configurations.

In an alternative embodiment of package 400, die pad 106 may be omitted, such as in the case of a leadframe for a package where the chip is electrically coupled to the laser-formed bond fingers 104a using a flip-chip technique.

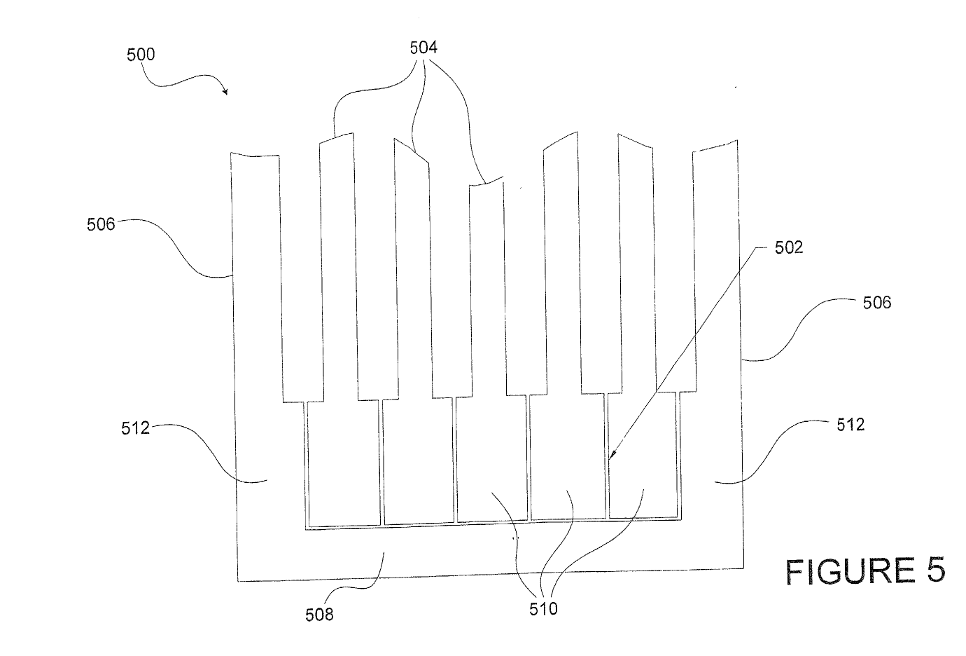

FIG. 5 is a plan view of an alternative embodiment of a leadframe 500 where the laser cutting method forms two or more leads that are integrally formed or tied together. Laser cuts 502 are made according to the methods disclosed herein, and these cuts form several leads 504. Laser cuts 502 also form two leads 506 that are joined or tied together by an integral bar 508 that is laser-formed from end block 200. Bar 508 extends transversely to the longitudinal direction of leads 506 around bond fingers 510 of leads 504 that are laterally between the two joined leads 506. The integral connection of leads 506 allows for a single bond wire or other electrical connection to a semiconductor chip, and also allows a common signal or potential to be communicated to or from a semiconductor chip on joined leads 506. The single bond wire or other connector may be connected to one of bond fingers 512 of joined leads 506 or to bar 508. The thickness of leads 504, including joined leads 506, and bar 508 may be reduced (e.g. by halfetching) to facilitate the laser forming step, as is discussed above with respect to FIG. 4.

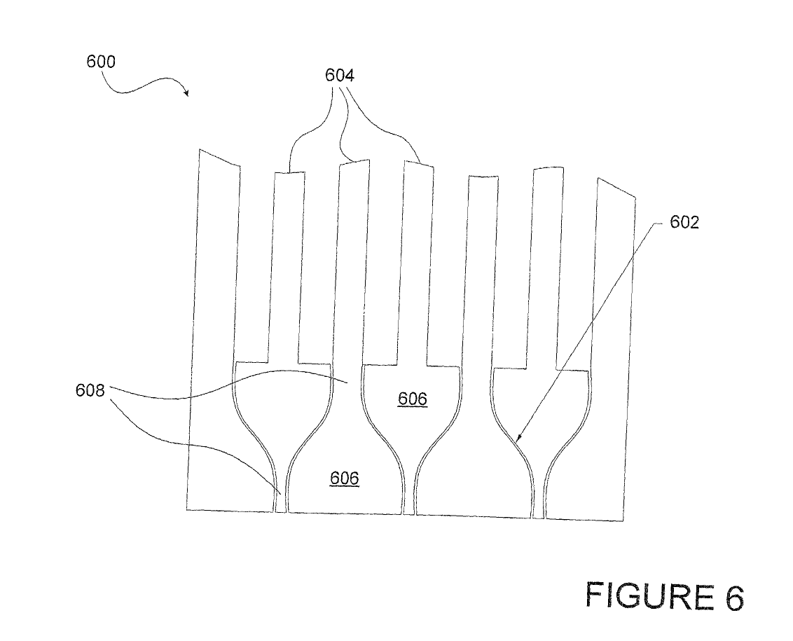

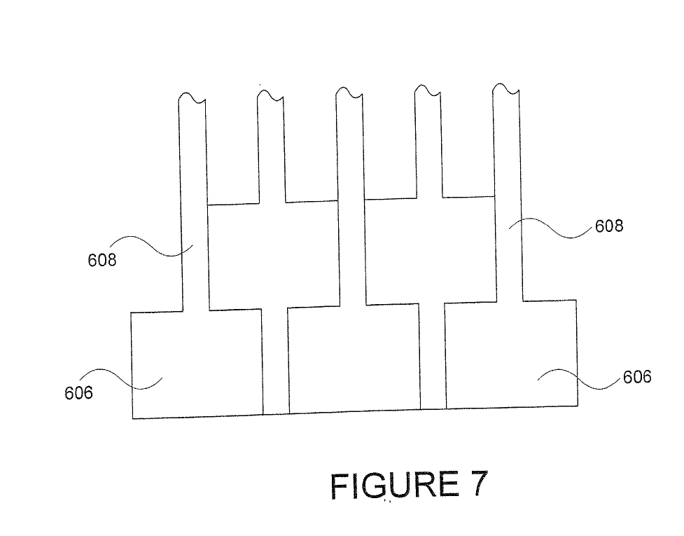

FIG. 6 is a plan view of an alternative embodiment of a leadframe 600 where laser cuts 602 form bond fingers 604 with a shape designed to optimize the bonding area of each bond finger 604, while allowing for an even tighter packing. For instance, when bond wires are attached to bond fingers, the actual bonds tend to be crescent-shaped due to the bonder capillary shape of thermosonic ball bonders. So in leadframe 600, bond fingers 604 have a wine-glass shape to accommodate the crescent-shaped bonds, where the wine-glass shape consists of a relatively wide body 606, and a narrower stem 608. The body 606 of each wine-glass shaped bond finger 604 has a semi-circular form that the crescent-shaped bond fits on. The lateral width of body 606 is wide enough to allow reliable bonding of a bond wire or another electrical conductor (e.g. a TAB bond) using conventional bonding equipment and methods.

To bring bond fingers 604 closer together, bond fingers 604 are laser-formed from an end block 200 in an alternating fashion such that adjacent wine-glass shapes are oriented in opposite directions, i.e., each wine-glass shape is rotated 180 degrees relative to adjacent wineglass shapes. So when one bond finger 604 has its body 606 proximate to the die pad, the flanking adjacent bond fingers 604 will have their stems 608 proximate to the die pad. This allows the body 606 of each bond finger 604 to squeeze between the stems 608 of adjacent bond fingers 604. Prior to laser-forming the wine-glass shaped bond fingers 604 from an end block 200, the thickness of end block 200 may be reduced so that the laser cutting step may be facilitated. Accordingly, bond fingers 604 would have a side profile similar to the leads 104 of FIG. 4.

Of course, the wine-glass shaped bond finger leads 604 of FIG. 6 are merely exemplary. The shape of the laser-formed bond fingers can be varied in a way that provides for a wider bond finger area where the actual connection will be made between the bond finger and the bond wire or other electrical conductor, and a narrow bond finger area where no connection is made. For instance, the bond fingers may have an alternating oppositely oriented T-shapes, as shown in FIG. 7.

Accordingly, the present invention uses a laser cutting technique to form finelypitched bond fingers of a leadframe. Unlike previously developed techniques for forming the bond fingers, in which a substantial amount of unused space was left between bond fingers of the leadframe, the laser beam forms ultra-narrow spaces between the bond fingers. This results in less wasted space and allows leads 104 and bond fingers 104a to be packed more tightly within leadframe 100.

While exemplary embodiments of the invention have been shown and described, it will be apparent to those skilled in the art that numerous alterations may be made without departing from the inventive concepts presented herein. For example, the entire portion of the lead 104 inward of dam bar 102 may be formed by etching or stamping into a block, and the block may then be cut with a laser to singulate the entire inner lead, including the bond finger 104a (see FIG. 1) and the second portion 104b of the lead 104. Thus, the invention is not to be limited except in accordance with the following claims and their equivalents.

What is claimed is:

1. A method of making a leadframe, the method comprising:
providing a metal sheet;
patterning the metal sheet to form a frame and plurality of leads that extend from the frame and are integrally joined in an end block at an inner end portion of the leads; and
cutting the end block with a laser to singulate the inner end portion of each lead from the end block.

2. The method of claim 1, further comprising reducing a thickness of the end block prior to the cutting with the laser.

3. The method of claim 1, wherein the cutting of the end block forms a wide area and a narrow area on the inner end portion of each lead.

4. The method of claim 3, wherein the location of the wide area and the narrow area alternates on adjacent leads.

5. The method of claim 3, wherein the wide area and the narrow area comprise a wine-glass shape.

6. The method of claim 3, further comprising reducing a thickness of the end block prior to the cutting with the laser.

7. The method of claim 1, wherein the cutting of the end block forms at least two leads that are integrallyjoined.

8. The method of claim 7, wherein the two leads that are integrally joined are joined by a bar, and the combination of the two integrally joined leads and the bar encloses the other leads.

9. A method of making a leadframe, the method comprising:
providing a metal sheet;
patterning the metal sheet to form the leadframe, wherein the leadframe includes a dam bar and at least one block of metal within and connected to the dam bar; and
patterning the block of metal with a laser to singulate a plurality of individual leads, wherein at least an inner end portion of each lead is formed by said patterning with the laser.

10. The method of claim 9, further comprising reducing a thickness of the block of metal prior to the patterning with the laser.

11. The method of claim 9, wherein the patterning of the block of metal forms a wide area and a narrow area on the inner end portion of each lead.

12. The method of claim 11, wherein the location of the wide area and the narrow area alternates on adjacent leads.

13. The method of claim 11, wherein the wide area and the narrow area comprise a wine-glass shape.

14. The method of claim 11, further comprising reducing a thickness of the block of metal prior to the patterning with the laser.

15. The method of claim 9, wherein the patterning of the block of metal forms at least two leads that are integrally joined.

16. The method of claim 15, wherein the two leads that are integrally joined are joined by a bar, and the combination of the two integrally joined leads and the bar encloses the other leads.

17. A method of making a semiconductor package, the method comprising:
providing a leadframe including a plurality of leads within and connected to a frame, wherein at least an inner end portion of each lead is singulated by laser cutting;
mounting a chip on the leadframe;
electrically coupling the chip to the inner end portion of a plurality of the leads; and
encapsulating the chip and the inner end portion of the leads.

18. The method of claim 17, wherein the inner end portion of each lead has a lesser thickness than an adjacent remaining portion of the lead.

19. The method of claim 17, wherein the laser cutting forms a wide area and a narrow area on the inner end portion of each lead.

20. The method of claim 19, wherein the location of the wide area and the narrow area alternates on adjacent leads.

21. The method of claim 19, wherein the wide area and the narrow area comprise a wine-glass shape.

22. The method of claim 19, wherein the inner end portion of each lead has a lesser thickness than an adjacent remaining portion of the lead.

23. The method of claim 17, wherein the laser cutting forms at least two leads that are integrally j oined.

24. The method of claim 23, wherein the two leads that are integrally joined are joined by a bar, and the combination of the two integrally joined leads and the bar encloses the other leads.

25. A leadframe comprising:
a plurality of leads extending from a frame toward a central region enclosed by the frame, wherein at least an inner end portion of each lead is singulated by laser cutting.

26. The leadframe of claim 25, wherein the inner end portion of the leads has a lesser thickness than a second portion of the leads between the inner end portion of the lead and the frame.

27. The leadframe of claim 25, wherein the laser cutting forms a wide area and a narrow area on the inner end portion of each lead.

28. The leadframe of claim 27, wherein the location of the wide area and the narrow area alternates on adjacent leads.

29. The leadframe of claim 27, wherein the wide area and the narrow area comprise a wine-glass shape.

30. The leadframe of claim 27, wherein the inner end portion of each lead has a lesser thickness than an adjacent remaining portion of the lead.

31. The leadframe of claim 25, wherein the laser cutting forms at least two leads that are integrally joined.

32. The leadframe of claim 31, wherein the two leads that are integrally joined are joined by a bar, and the combination of the two integrally joined leads and the bar encloses the other leads.

33. The leadframe of claim 29, wherein the wine-glass shape of each of a first subset of the leads is oriented in a first direction, the wine-glass shape of each of a second subset of the leads is oriented in a second direction opposite that of the first direction, and individual leads of the first subset are situated in an alternating lateral pattern with individual leads of the second subset such that the wine-glass shape of adjacent inner end portions are oriented in opposite directions.

34. A semiconductor package comprising:
a plurality of metal leads, wherein at least an inner end portion of each lead is singulated by laser cutting;
a semiconductor chip electrically coupled to the inner end portion of a plurality of the leads; and
an encapsulating material covering the semiconductor chip and the inner end portion of the leads.

35. The semiconductor package of claim 34, wherein the inner end portion of each of the leads is between the chip and an adjacent second portion of the lead, and the inner end portion of the lead has a lesser thickness than the adjacent second portion of the lead.

36. The semiconductor package of claim 34, wherein the laser cutting forms a wide area and a narrow area on the inner end portion of each lead.

37. The semiconductor package of claim 36, wherein the location of the wide area and the narrow area alternates on adjacent leads.

38. The semiconductor package of claim 36, wherein the wide area and the narrow are comprise a wine-glass shape.

39. The semiconductor package of claim 36, wherein the inner end portion of each lead has a lesser thickness than an adjacent remaining portion of the lead.

40. The semiconductor package of claim 34, wherein the laser cutting forms at least two leads that are integrally joined.

41. The semiconductor package of claim 40, wherein the two leads that are integrally joined are joined by a bar, and the combination of the two integrally joined leads and the bar encloses the other leads.
